(19) United States
(12) Patent Application Publication
(10) Pub. No.: US 2025/0237941 A1
(43) Pub. Date: Jul. 24, 2025

(54) PELLICLE FOR EUV APPLICATIONS

(71) Applicant: Taiwan Semiconductor Manufacturing Company, LTD., Hsinchu (TW)

(72) Inventors: Pei-Hsun Tsai, Hsinchu (TW); Kelvin Elphick, Hsinchu (TW); Hung Lin Chen, Taipei (TW); Tienchi Ji, Hsinchu (TW); Po-Wen Chung, Tainan (TW); Cheng En Chung, Hsinchu (TW); Ching-Ho Hsu, Yunlin (TW); Yu-Ting Chen, Keelung (TW); Min-Tin Hsu, Hsinchu (TW); Chuan Yu Wei, New Taipei (TW); Chien-Chao Huang, Hsinchu (TW); Fei-Gwo Tsai, Taipei (TW); Chih-Chiang Tu, Tauyen (TW); Jui-Chun Weng, Taipei (TW); You-Cheng Jhang, Changhua (TW); Ching-Yueh Chen, Hsinchu (TW); Yun-Yue Lin, Hsinchu (TW); Da-Jiun Wang, Chiayi (TW); Yu Fan Chuang, Yilan (TW)

(21) Appl. No.: 18/417,128

(22) Filed: Jan. 19, 2024

(51) Int. Cl. G03F 1/62; H01L 21/027; H01L 21/3213

(52) U.S. Cl. CPC G03F 1/62; H01L 21/027; H01L 21/32134; H01L 21/32139

(57) ABSTRACT

A pellicle membrane is formed from a core layer and two capping layers of specified structure. In some embodiments, the core layer includes a high percentage of the Mo₃Si crystal phase. In other embodiments, the capping layers comprise silicon oxynitride or silicon carbon nitride. The resulting pellicle membrane has a combination of high transmittance for EUV light and low reflectivity of both EUV and DUV light.

### BACKGROUND

A photolithographic patterning process uses a reticle (i.e. photomask) that includes a desired mask pattern. The reticle may be a reflective mask or a transmission mask. In the process, ultraviolet light is reflected off the surface of the reticle (for a reflective mask) or transmitted through the reticle (for a transmission mask) to transfer the pattern to a photoresist on a semiconductor wafer. The minimum feature size of the pattern is limited by the light wavelength. Extreme ultraviolet (EUV) light, which spans wavelengths from 124 nanometers (nm) down to 10 nm, is currently being used to provide small minimum feature sizes. At such short wavelengths, particle contaminants on the photomask can cause defects in the transferred pattern.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a side cross-sectional view of a first example pellicle membrane, in accordance with some embodiments of the present disclosure.

FIG. 2 is a side cross-sectional view of a second example pellicle membrane, in accordance with some embodiments of the present disclosure.

FIG. 3 is a flow chart illustrating a first method for making a pellicle membrane and/or a pellicle assembly, in accordance with some embodiments.

FIG. 4 is a side cross-sectional view of a substrate prior to beginning the method of FIG. 3.

FIG. 5 is a side cross-sectional view of the substrate after applying a first outer sublayer upon the substrate.

FIG. 6 is a side cross-sectional view of the substrate after applying a first inner sublayer upon the substrate.

FIG. 7 is a side cross-sectional view of the substrate after applying a core layer upon the substrate.

FIG. 8 is a side cross-sectional view of the substrate after applying a second inner sublayer upon the substrate.

FIG. 9 is a side cross-sectional view of the substrate after applying a second outer sublayer upon the substrate.

FIG. 10 is a side cross-sectional view of the substrate after applying a hardmask to the backside of the substrate.

FIG. 11 is a side cross-sectional view of the substrate after the hardmask has been patterned.

FIG. 12 is a side cross-sectional view of the substrate after etching is performed to release the pellicle membrane and form a subframe.

FIG. 13A is a side cross-sectional view of the substrate and subframe after the hardmask is removed.

FIG. 13B is a lower plan view of the substrate and subframe after the hardmask is removed.

FIGS. 14A-14C are different views of a mounting frame, in accordance with some embodiments. FIG. 14A is a plan cross-sectional view, FIG. 14B is a first side view, and FIG. 14C is a front side view.

FIG. 15 is a side cross-sectional view of the substrate and subframe after attachment to a mounting frame, also referred to as a pellicle assembly.

FIG. 16 is a side cross-sectional view of the pellicle assembly attached to an EUV reticle or photomask.

FIG. 17 is a flow chart illustrating a second method for making a pellicle membrane and/or a pellicle assembly, in accordance with some embodiments.

FIG. 18 is an illustration of an extreme ultraviolet (EUV) photolithography system for processing a semiconductor wafer substrate, in accordance with some embodiments.

FIG. 19 is a flow chart illustrating a method for processing a semiconductor wafer substrate, in accordance with some embodiments.

FIGS. 20A-20C are diagrams illustrating some steps of the method for processing a semiconductor wafer substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure may refer to temperatures for certain process steps. It is noted that these generally refer to the temperature at which the heat source (e.g. furnace) is set, and do not necessarily refer to the temperature which must be attained by the material being exposed to the heat.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to pellicle membranes having particular structures as described herein, and methods for making and using such pellicle membranes. At EUV light wavelengths, particle contaminants on the reticle (i.e. photomask) can cause defects in the transferred pattern. Thus, a pellicle assembly (or simply pellicle) is used to protect the reticle from such particles. The pellicle assembly includes a pellicle membrane which is attached to a mounting frame. The mounting frame supports the pellicle membrane over the reticle. Any contaminating particles which land on the pellicle membrane are thus kept out of the focal plane of the reticle, thus reducing or preventing defects in the transferred pattern. The pellicle membranes of the present disclosure include a specified core layer and/or specified capping layers to enhance EUV transmittance, reduce EUV reflectivity, and improve mechanical properties.

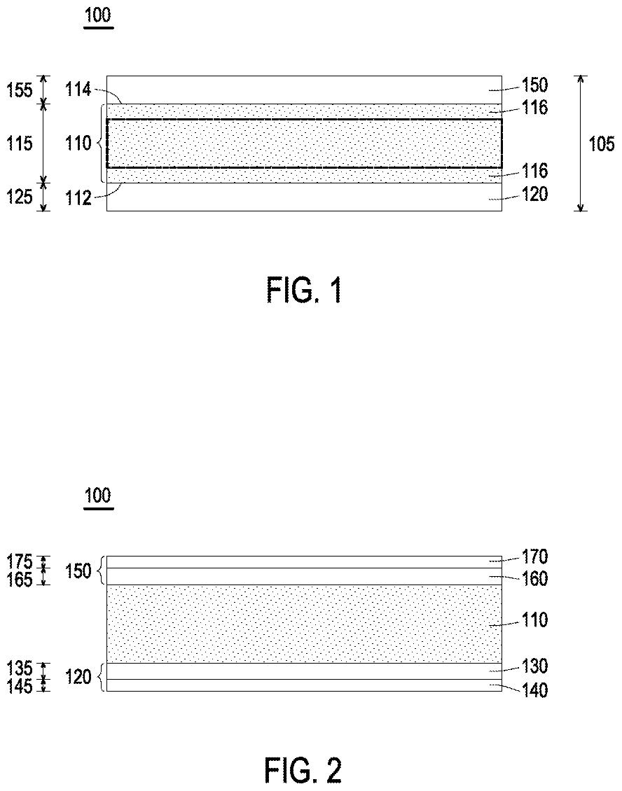

FIG. 1 is a side cross-sectional view of a first example pellicle membrane, in accordance with some embodiments of the present disclosure. The pellicle membrane 100 is formed from a core layer 110 having a first surface 112 and a second surface 114. The core layer has a thickness 115 which is the distance between the first surface 112 and the second surface 114. Put another way, the first surface and the second surface are on opposite sides of the core layer. In particular orientations, the first surface 112 can also be considered a lower surface, and the second surface 114 can also be considered an upper surface of the pellicle membrane. A first capping layer 120 is present on the first surface 112 of the core layer. A second capping layer 150 is present on the second surface 114 of the core layer. The first capping layer has a thickness 125, and the second capping layer has a thickness 155.

In particular embodiments, the thickness 115 of the core layer may range from about 8 nanometers (nm) to about 12 nm. In particular embodiments, the thickness 125, 155 of each capping layer may range independently from about 1 nm to about 5 nm. In particular embodiments, the thickness 105 of the pellicle membrane may be from about 10 nm to about 30 nm. However, other values and ranges for each of these thicknesses are also within the scope of this disclosure. Overly high thicknesses may result in EUV transmission loss. However, overly low thicknesses may reduce membrane stability and integrity.

In some embodiments of the present disclosure, the core layer 110 includes different crystal phases of molybdenum (Mo) and silicon (Si), also known as molybdenum silicides. In particular embodiments, the core layer includes the Mo₃Si crystal phase. Other crystal phases which may be present include Mo₅Si₃ and MoSi₂. In some embodiments, the core layer may also be nitridated or oxidated to form, for example, silicon nitride (SiN). This can be done to control the mechanical properties and EUV transmittance of the core layer. Very generally, then, the core layer may be described as being formed from MoSiₓN_{y}, where 0≤x, y≤1, which can also be abbreviated as MoSiN.

In particular embodiments, the core layer comprises about 30 at % or more of Mo₃Si. The core layer may also comprise a minimum of 30 at % of Mo₃Si. In some embodiments, the core layer may comprise about 30 at % to about 50 at % of Mo₅Si₃. In other embodiments, the core layer comprises more than 50 at % of Mo₅Si₃. The core layer may comprise from about 10 at % to about 30 at % of MoSi₂. Similarly, the core layer may comprise from about 10 at % to about 30 at % of SiN. In more specific embodiments, the core layer comprises from about 30 at % to about 40 at % of the SiN and the MoSi₂ combined, and in other embodiments about 40 at % or less of the SiN and the MoSi₂ combined (but greater than zero). Combinations of these ranges are also contemplated. Other values and ranges for each of these amounts are also within the scope of this disclosure.

The molar or atomic ratio of silicon to molybdenum (Si:Mo) in the core layer may affect the emissivity (i.e. transmittance) of EUV radiation of the pellicle membrane. In particular embodiments, the Si:Mo molar ratio is 1:1 or lower. In other words, there is more molybdenum than silicon in the core layer. At such values, the emissivity is about 0.35 or greater.

The structure of the core layer can be controlled, for example using two phase nano-grain composites and/or optimizing the amount of hydrogen remaining in the core layer. It is noted that the various crystal phases in the core layer may not be evenly dispersed throughout the thickness of the core layer. Gradients may be present in the core layer for each of the crystal phases. In particular embodiments, in the 2 nm that are closest to the first surface 112 and the second surface 114 of the core layer, the Mo₅Si₃ dominates, or in other words those portions of the core layer contain at least 50 at % of Mo₅Si₃. Those portions 116 of the core layer are shown in dashed lines.

The first capping layer 120 and the second capping layer 150 are used to enhance various properties of the pellicle membrane. In particular, they can increase the EUV exposure tolerance of the pellicle membrane and increase oxidation resistance. In particular embodiments, the first capping layer and the second capping layer are made of the same material, and in other embodiments they can be made from different materials. In some particular embodiments, the first capping layer and the second capping layer independently comprise silicon carbide (SiCₓ, 0<x≤1), or silicon oxycarbide (SiOₓC_{y}, 0<x, y≤1), or silicon carbon nitride (SiCₓN_{y}, 0<x, y≤1), or silicon oxide (SiOₓ, 0<x≤1), or silicon nitride (SiNₓ, 0<x≤1), or silicon oxynitride (SiOₓN_{y}, 0<x, y≤1). It is noted that silicon carbide may be abbreviated as SiC, silicon oxycarbide may be abbreviated as SiOC, silicon carbon nitride may be abbreviated as SiCN, silicon oxide may be abbreviated as SiO, silicon nitride may be abbreviated as SiN, and silicon oxynitride may be abbreviated as SiON. As illustrated here, the two capping layers 120, 150 are a single-layer structure.

In some specific embodiments, the capping layers 120, 150 independently comprise SiC, SiOC, or SiCN. In embodiments using SiCN, the amount of carbon may range from 0 to about 40 at % of the capping layer. These materials are useful for oxidation resistance. In these embodiments, the core layer 110 can be made of any suitable material, and may or may not include Mo₃Si. For example, the core layer could be made of ZrSiₓO_{y}N_{z} (0<x, y, z≤1), niobium (Nb) alloys, carbon nanotubes, silicon nanowires, or other metal silicides.

FIG. 2 is a side cross-sectional view of a second example pellicle membrane, in accordance with some embodiments of the present disclosure. In this embodiment, each capping layer 120, 150 is a multi-layer structure. Here, each capping layer includes an inner sublayer 130, 160 and an outer sublayer 140, 170. Each inner sublayer 130, 160 directly contacts the core layer 110. Each outer sublayer 140, 170 directly contacts a respective inner sublayer on one side, and is exposed on the opposite surface.

Each inner sublayer 130, 160, is made of a different material than its corresponding outer sublayer 140, 170. In some particular embodiments, though, the inner sublayer 130 of the first capping layer and the inner sublayer 160 of the second capping layer are made of the same material. Similarly, the outer sublayer 140 of the first capping layer and the outer sublayer 170 of the second capping layer may also be made of the same material in those particular embodiments. The inner sublayers 130, 160 and outer sublayers 140, 170 are typically made from a dielectric material.

The inner sublayer 130 of the first capping layer has a thickness 135. The outer sublayer 140 of the first capping layer has a thickness 145. The inner sublayer 160 of the second capping layer has a thickness 165. The outer sublayer 170 of the second capping layer has a thickness 175. In particular embodiments, each of these thicknesses 135, 145, 165, 175 is independently from about 1 nm to about 5 nm. However, other values and ranges for each of these thicknesses are also within the scope of this disclosure.

In some specific embodiments, the inner sublayer 130 of the first capping layer is thicker than the outer sublayer 140 of the first capping layer, and the inner sublayer 160 of the second capping layer is thicker than the outer sublayer 170 of the second capping layer. In more specific embodiments, the ratio of the thickness 135, 165 of the inner sublayer to the thickness 145, 175 of the outer sublayer may be from about 1:1 to about 3:2. Again, other ratios are within the scope of this disclosure.

In some specific embodiments, the inner sublayers 130, 160 comprise silicon dioxide (SiO₂). In some other specific embodiments, the outer sublayers 140, 170 comprise SiOₓC_{y} or SiCₓN_{y}, where 0<x, y≤1. In these embodiments, the core layer 110 can be made of any suitable material, and may or may not include Mo₃Si, as previously described.

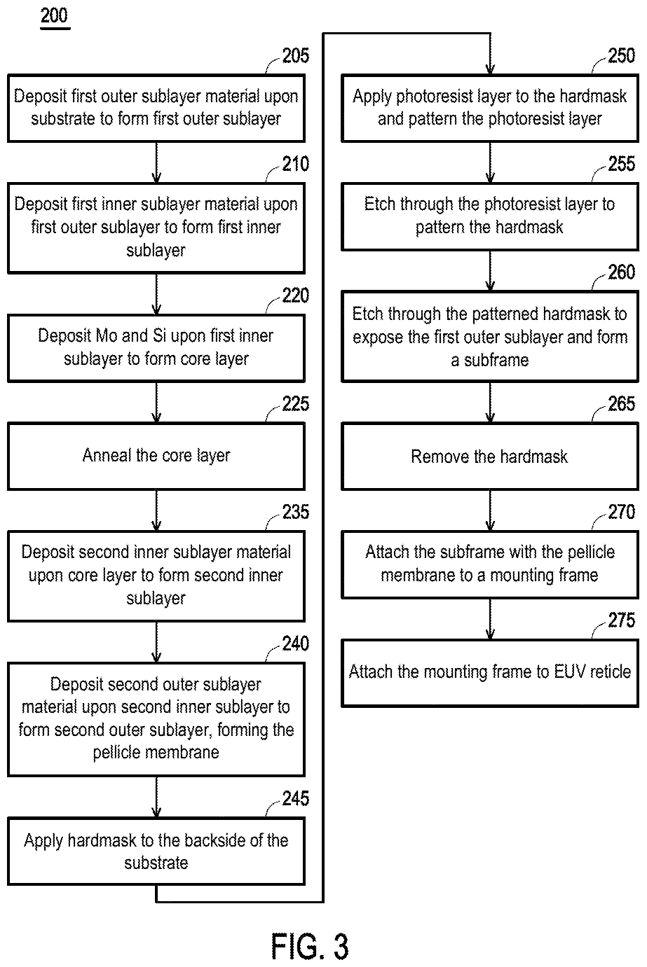

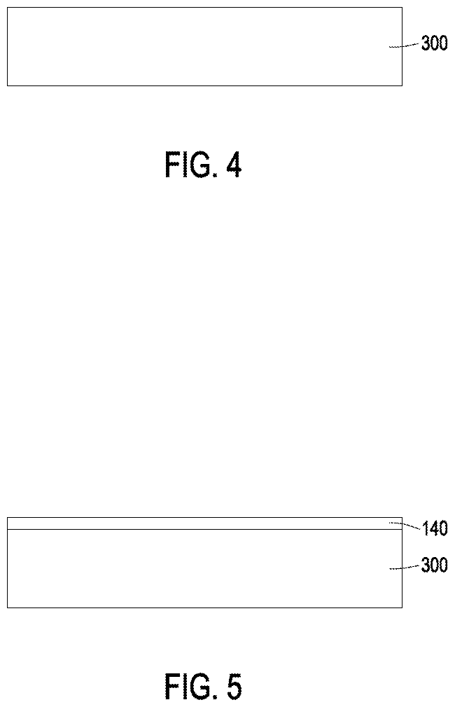

FIG. 3 is a flow chart illustrating a first method 200 for making a pellicle membrane and a pellicle assembly, in accordance with some embodiments. Some steps of the method are also illustrated in FIGS. 4-16, which are side cross-sectional views. These figures provide different views for better understanding. While the method steps are discussed below in terms of forming a pellicle membrane and pellicle assembly, such discussion should also be broadly construed as applying to the formation of multiple pellicle membranes concurrently.

FIG. 4 is a cross-sectional view of a substrate 300 upon which the pellicle membrane will be formed. The substrate may be, for example, a wafer made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the substrate is silicon.

Next, in step 205 of FIG. 3 and as illustrated in FIG. 5, a first outer sublayer 140 is formed upon the substrate 300. This may be done by depositing a first outer sublayer material (as previously described) upon the substrate. Such deposition may be performed by chemical vapor deposition (CVD), physical vapor deposition (PVD), atomic layer deposition (ALD), or other suitable deposition technique. Depending on the desired composition of this sublayer, the deposition may be performed in an oxygen-enriched or nitrogen-enriched atmosphere.

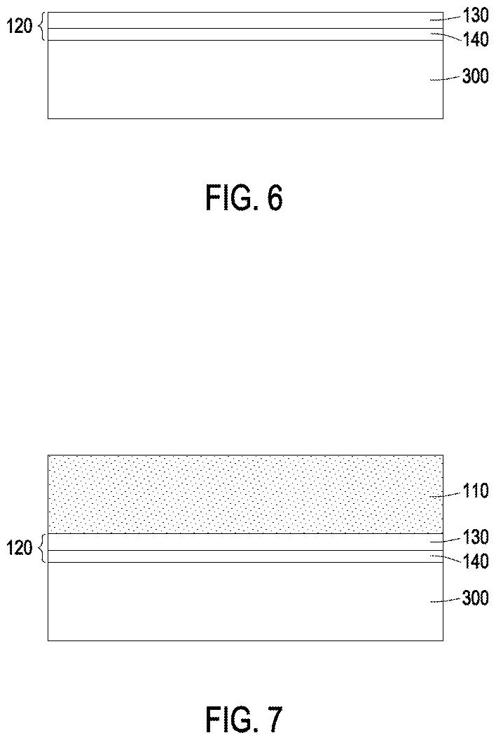

After the first outer sublayer 140 is formed, in step 210 of FIG. 3 and as illustrated in FIG. 6, a first inner sublayer material is deposited upon the first outer sublayer 140 to form a first inner sublayer 130 upon the substrate 300. CVD, PVD, ALD, or other suitable deposition technique may be used. The first capping layer 120 is thus formed.

Then, in step 220 of FIG. 3 and as illustrated in FIG. 7, the core layer 110 is formed upon the first inner sublayer 130. In some embodiments, this is done by depositing molybdenum and silicon upon the substrate in a desired molar ratio. This may be done by CVD, PVD, or ALD. Crystal phases of Mo₃Si, Mo₅Si₃, and MoSi₂ are thus formed. When done in a nitrogen-enriched atmosphere, SiN may also be formed. As noted in step 225 of FIG. 3, annealing of the core layer may also be performed. In particular embodiments, the annealing temperature is from about 800° C. to about 1200° C. In some embodiments, the annealing may be performed for a time period of about 1 hour to about 8 hours. The annealing may be performed in a non-reactive environment, for example, under an argon atmosphere. In embodiments where the capping layers/sublayers comprise SiOC or SiCN, the core layer may be made of any suitable material.

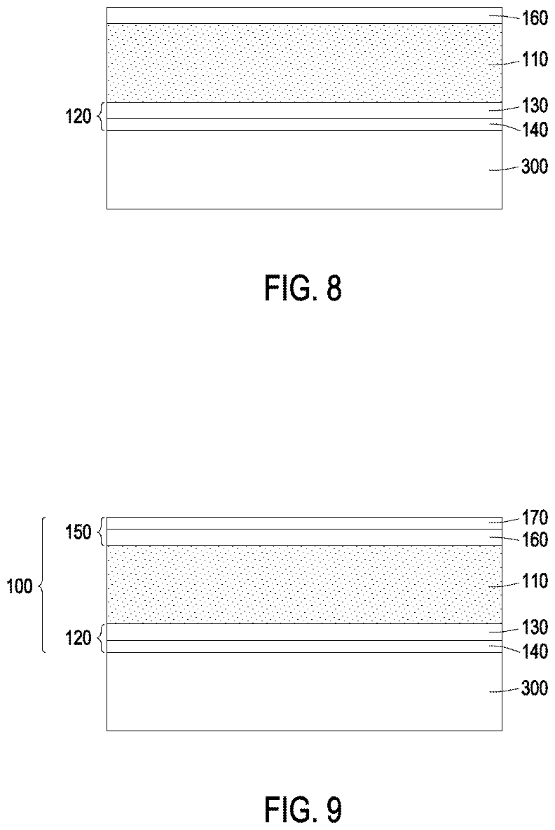

Next, in step 235 of FIG. 3 and as illustrated in FIG. 8, a second inner sublayer 160 is formed upon the core layer 110 by deposition of a second inner sublayer material. CVD, PVD, ALD, or other suitable deposition technique may be used.

After the second inner sublayer 160 is formed, in step 240 of FIG. 3 and as illustrated in FIG. 9, a second outer sublayer material is deposited upon the second inner sublayer 160 to form a second outer sublayer 170 upon the substrate 300. CVD, PVD, ALD, or other suitable deposition technique may be used. The second capping layer 150 is thus formed. The pellicle membrane 100 is thus completed, and includes the first capping layer 120, the core layer 110, and the second capping layer 150.

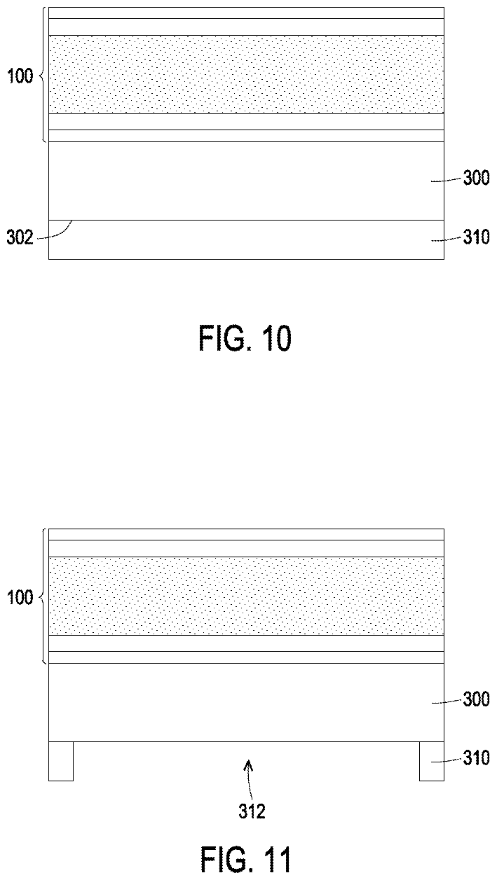

Next, in step 245 of FIG. 3 and as illustrated in FIG. 10, a hardmask 310 is applied to the backside 302 of the substrate 300. The hardmask may be formed from any suitable dielectric material. The hardmask 310 may have any suitable thickness 315, for example, a thickness of about 100 nm to about 1000 nm. The hardmask can be applied by CVD, PVD, ALD, or any other suitable technique. In particular embodiments, the hardmask is SiN or SiON.

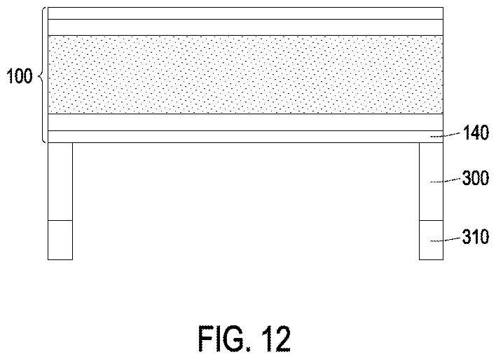

Then, in step 250 of FIG. 3, a photoresist layer is applied to the hardmask and patterned. In step 255 of FIG. 3, the exposed portions of the hardmask 310 are etched away, transferring the pattern to the hardmask. FIG. 11 illustrates the resulting structure after the photoresist layer has been removed. In this cross-sectional view, an opening 312 has been formed in the hardmask 310. Next, in step 260 of FIG. 3 and as illustrated in FIG. 12, etching is performed through the patterned hardmask to remove the exposed portions of the substrate 300, exposing the first outer sublayer 140. It is noted the first outer sublayer acts as an etch stop layer in this process step.

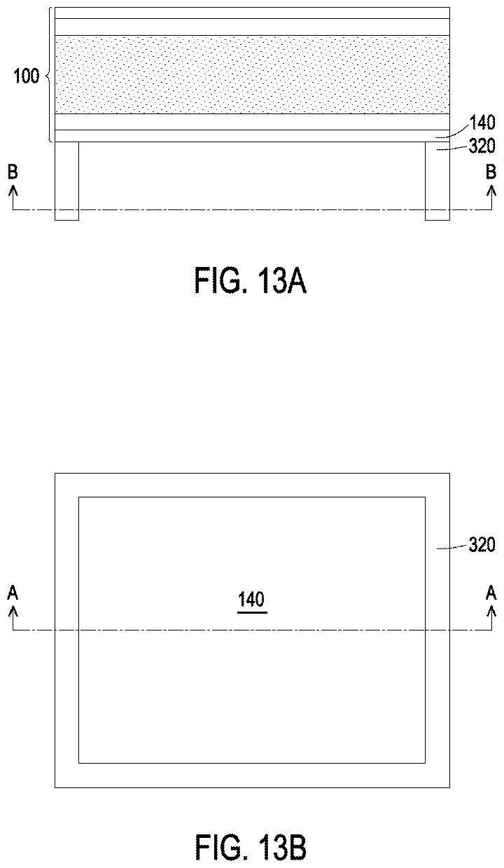

In step 265 of FIG. 3, the hardmask is then removed. FIG. 13A and FIG. 13B illustrate different views of the structure after this step. FIG. 13A is a cross-sectional view, and FIG. 13B is a lower plan view. The cross-sectional view of FIG. 13A is taken along line A-A of FIG. 13B. Similarly, the plan view of FIG. 13B is taken upwards through line B-B of FIG. 13A. The substrate now takes the form of a subframe 320 which supports the pellicle membrane 100 on four sides, as best seen in FIG. 13B.

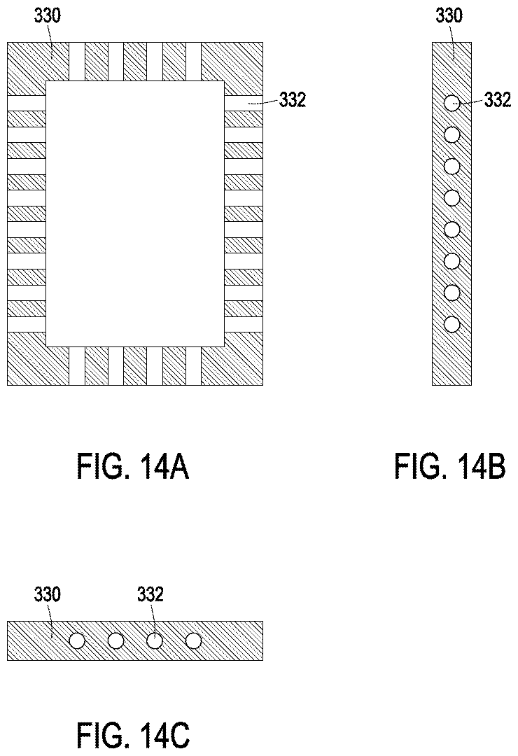

Next, in step 270 of FIG. 3, the pellicle membrane 100 and subframe 320 are attached to a mounting frame 330. FIGS. 14A-14C are different views of the mounting frame 330, according to some embodiments of the present disclosure. FIG. 14A is a plan cross-sectional view in which the plane cuts through the vent holes 332, FIG. 14B is a Y-axis side view, and FIG. 14C is an X-axis side view. Vent holes 332 are visible on all sides of the mounting frame. However, it is contemplated that vent holes may be present on only one, two, or three sides of the mounting frame. The mounting frame can be made from suitable materials such as anodized aluminum, stainless steel, plastic, silicon (Si), titanium, silicon dioxide, aluminum oxide (Al₂O₃), or titanium dioxide (TiO₂). Vent holes 332 may be present in the mounting frame 330 for equalizing pressure on both sides of the pellicle membrane. In some embodiments, the total area of the vent holes can range from zero to about 100 square millimeters (mm²).

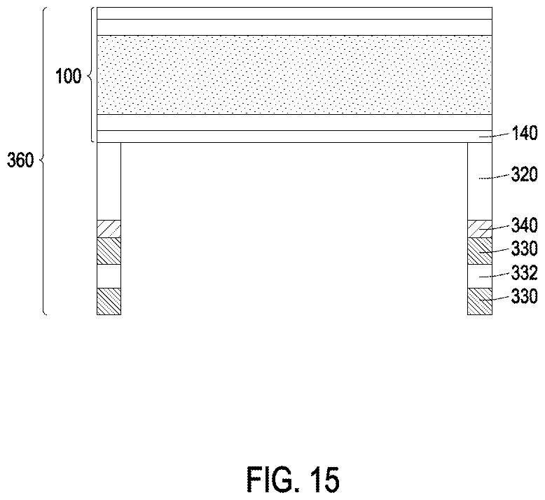

FIG. 15 is a side view of the resulting pellicle assembly 360. The pellicle assembly includes a pellicle membrane 100 which is attached to a mounting frame 330, for example using an adhesive layer 340. The mounting frame supports the pellicle membrane over the reticle.

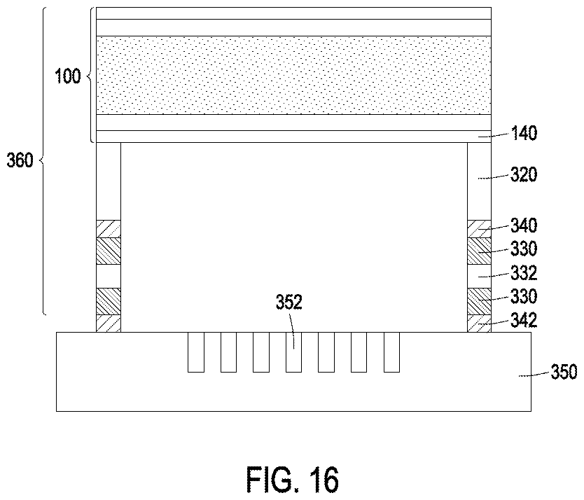

Finally, in step 275 of FIG. 3 as illustrated in FIG. 16, the pellicle assembly 360 is attached to a reticle 350. As illustrated here, the EUV reticle 350 includes a patterned image 352. The mounting frame 330 is joined to the reticle via adhesive layer 342, but could alternatively be joined via, for example, mechanical attachment. The pellicle membrane 100 protects the patterned image 352 from particle contaminants.

It is noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

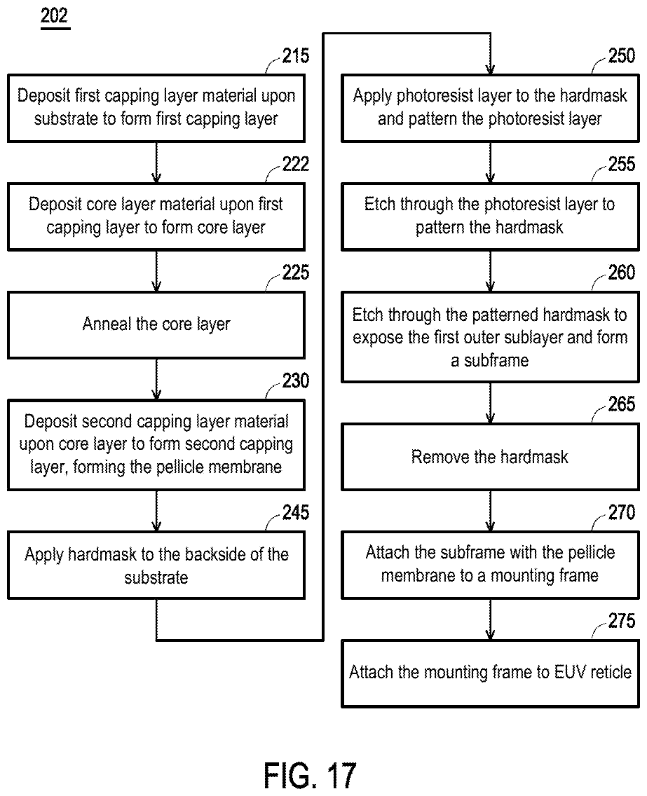

FIG. 17 is a flow chart illustrating a second method 202 for making a pellicle membrane and a pellicle assembly, in accordance with some embodiments. This method is substantially similar to the method illustrated in FIG. 3. It differs in that a first capping layer 120 is deposited upon the substrate in step 215, and a second capping layer 150 is deposited upon the core layer 110 in step 230. It also differs in that step 222 indicates a core layer is formed without specifying the material used, for those embodiments in which the capping layers comprise SiOC or SiCN. The resulting structure of the pellicle membrane 100 is thus like that illustrated in FIG. 1 instead.

The resulting pellicle membrane has reduced stress levels, and is a relatively stable and dense film. Because the pellicle membrane is in the optical path between the reticle and the wafer upon which the transferred pattern is to be imaged, the membrane may be exposed to energies from 250 watts to higher than 400 watts. This can cause the pellicle membrane to quickly rise to temperatures over 800° C.

Certain optical properties are thus desired for the pellicle membrane. For example, the pellicle membrane should have high transmittance (i.e. optically transparent) for EUV wavelengths, low reflectivity for EUV wavelengths, low non-uniformity, and low scattering. The EUVT % measures the percentage of light transmission of the EUV light wavelength (more specifically, 13.5 nm). A higher EUVT % is desired. The EUVT U % is known as the non-uniformity, and measures how uniform the light transmission is. A lower U % is desired. The EUVR % measures the reflectance of the EUV light wavelength (13.5 nm). This can be considered to be the amount of the EUV light that is reflected by the pellicle membrane and so does not reach the reticle itself. In addition, such reflected EUV light may be reflected towards the photoresist and cause exposure, which is undesirable. A lower EUVR % is desired. In addition, desirably the pellicle membrane has low reflectance for deep ultraviolet (DUV) wavelengths, such as at 193 nm and 248 nm. Again, these wavelengths may be reflected towards the photoresist and also cause undesired exposure. This may be measured as the DUVR %, and a lower value is desired. In particular, the use of multiple sublayers (as in FIG. 2) may aid in obtaining a desired combination of properties for the pellicle membrane.

In some particular embodiments, the EUVT % when measured at an EUV wavelength of 13.5 nm is at least 88%, or at least 90%, or at least 92%. In some particular embodiments, the EUVT U % may be less than 0.4%. In some further embodiments, the EUVT U % may be from about 0.1% to about 0.2%. In some particular embodiments, the EUVR % is less than 0.05%, or less than 0.02%. In some particular embodiments, the DUVR % (193 nm) is less than 25%, or less than 20%. In some particular embodiments, the DUVR % (248 nm) is less than 25%, or less than 20%. All combinations of any number of these properties are contemplated as being within the scope of this disclosure, though they are not expressly spelled out herein.

In addition, the pellicle membrane desirably has a high stiffness to minimize any potential sagging or deflection that may occur over time. For example, the dimensions of the pellicle membrane (length and width) are on the order of about 100 millimeters. The pellicle membranes of the present disclosure may sag or deflect in the range of about 200 μm to about 300 μm under an applied pressure differential of two pascals (Pa). The pellicle membrane has high durability and resistance to particle damage or chemical reactions during exposure in an EUV environment.

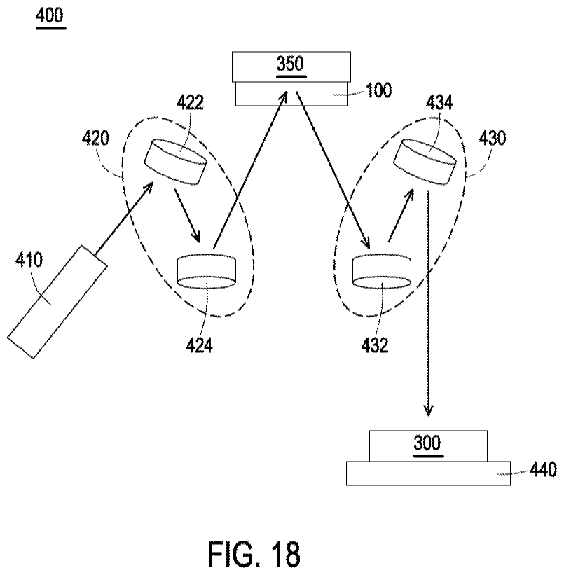

FIG. 18 is an illustrative schematic diagram, not drawn to scale, illustrating the various components of an extreme ultraviolet (EUV) photolithography system in which the pellicle membrane 100 is used. Generally, the EUV photolithography system 400 begins with an EUV light source 410 that generates EUV light or radiation. Downstream of the EUV light source is an illumination stage 420 in which the EUV light may be collected and focused as a beam, for example using field facet mirror 422 that splits the beam into a plurality of light channels. These light channels can then directed using one or more relay mirrors 424 onto the plane of the photomask. The photomask 350 may include a pellicle membrane 100, through which the radiation passes before and/or after contacting the photomask. Downstream of the photomask 350 is the projection optics module 430, which is configured for imaging the pattern of the photomask onto the semiconductor wafer substrate 300. The projection optics module 430 may include refractive optics or reflective optics for carrying the image of the pattern defined by the photomask. Illustrative mirrors 432, 434 are shown. The wafer substrate 300 is positioned upon a wafer stage 440, which can move as necessary for imaging. The lithography system can include other modules or be integrated with or coupled to other modules.

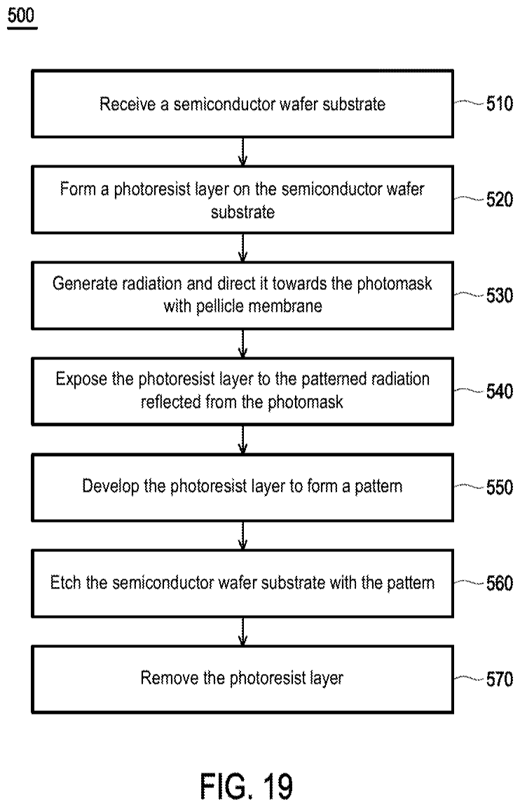

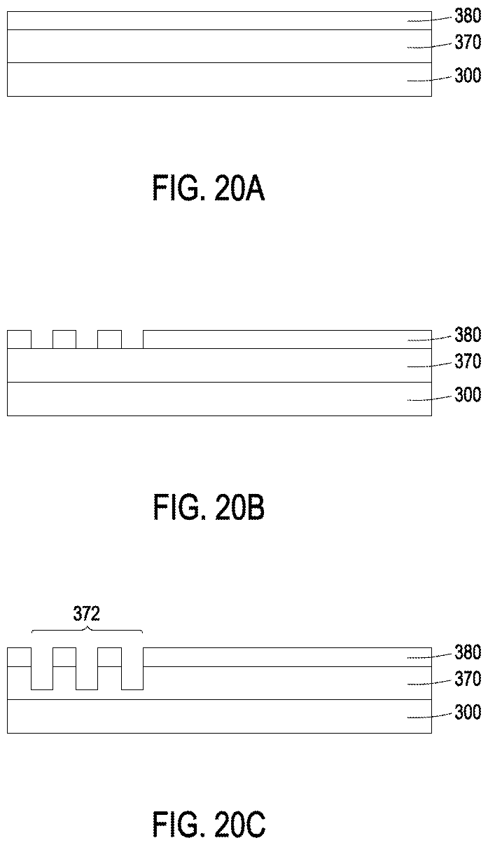

FIG. 19 is a flowchart illustrating a method 500 for processing a semiconductor wafer substrate, in accordance with some embodiments. FIGS. 20A-20C illustrate some of the steps in this method.

In step 510 of FIG. 19, a semiconductor wafer substrate is received. The substrate is placed in a fixed location within a photolithographic device. In step 520, a photoresist (PR) layer is formed on the semiconductor wafer substrate.

FIG. 20A is a side cross-sectional view of the wafer substrate after step 520. Here, as an example, a metal layer 370 is present on the semiconductor wafer substrate 300, and the photoresist layer 380 is present upon the metal layer.

Continuing, then, in step 530 of FIG. 19, radiation is generated and directed at the photomask or reticle using a photolithography system (such as that illustrated in FIG. 18). In step 540, the PR layer is exposed to the patterned radiation reflected from the photomask. The radiation passes through a pellicle membrane as described herein. The exposed portion of the photoresist is photochemically modified. In step 550, the PR layer is developed, such that the pattern from the photomask is now made in the PR layer. This is illustrated in FIG. 20B.

Next, in step 560 of FIG. 19, the wafer substrate is etched to transfer the pattern to the substrate. This can be done, for example, using dry etching or wet etching. Referring now to FIG. 20C, trenches 372 are now present in the metal layer 370. In step 570 of FIG. 19, the PR layer is removed. Additional processing steps may then be performed to fabricate a semiconductor device or integrated circuit. Examples of such steps may include ion implantation, deposition of other materials, etching, etc.

Additional processing steps may be performed to fabricate a semiconductor device or integrated circuit. Examples of such steps may include ion implantation, deposition of other materials, etching, etc.

Some embodiments of the present disclosure thus relate to a pellicle membrane, comprising a core layer, a first capping layer, and a second capping layer. The core layer has a first surface and a second surface, and comprises SiN, MoSi₂, Mo₅Si₃, and Mo₃Si. The first capping layer is on the first surface of the core layer. The second capping layer is on the second surface of the core layer.

Also disclosed in various embodiments are methods for making a pellicle membrane. A first capping layer material is deposited upon a substrate to form a first capping layer. Molybdenum and silicon are deposited upon the first capping layer to form a core layer that comprises about 30 at % or more of Mo₃Si. A second capping layer material is deposited upon the core layer to form a second capping layer and obtain the pellicle membrane. In some further processing steps, the core layer of the pellicle membrane may be annealed before forming the second capping layer. A hardmask is applied to a backside of the substrate. The hardmask is patterned. Etching is then performed through the patterned hardmask to obtain the pellicle membrane attached to a subframe.

Some other embodiments of the present disclosure relate to a pellicle membrane, comprising a core layer, a first capping layer, and a second capping layer. The core layer has a first surface and a second surface. The first capping layer is on the first surface of the core layer. The second capping layer is on the second surface of the core layer. The capping layers may include sublayers. The capping layers or the outer sublayers comprise SiOₓC_{y} or SiCₓN_{y}, where 0<x, y≤1.

Also disclosed in various embodiments are methods for making a pellicle membrane. A first capping layer material is deposited upon a substrate to form a first capping layer. A core layer is formed upon the first capping layer. A second capping layer material is deposited upon the core layer to form a second capping layer and obtain the pellicle membrane. In some further processing steps, the core layer of the pellicle membrane may be annealed before forming the second capping layer. The capping layers or the outer sublayers comprise SiOₓC_{y} or SiCₓN_{y}, where 0<x, y≤1. A hardmask is applied to a backside of the substrate. The hardmask is patterned. Etching is then performed through the patterned hardmask to obtain the pellicle membrane attached to a subframe.

Also disclosed herein are various methods of forming a pellicle assembly. A pellicle membrane attached to a subframe is made as described above. The subframe is then attached to a mounting frame to obtain the pellicle assembly.

Also disclosed herein are methods for processing a semiconductor wafer substrate. A semiconductor wafer substrate is received. A photoresist layer is formed on the semiconductor wafer substrate. The photoresist layer is exposed to radiation from a reflective photomask in a photolithography system. The radiation passes through a pellicle membrane that comprises a first capping layer, a core layer that comprises Mo₃Si, and a second capping layer. The photoresist layer is then developed. The exposed layer below the photoresist layer may be etched, or an additional layer may be deposited, or other processing operations may occur.

The methods, systems, and devices of the present disclosure are further illustrated in the following non-limiting working examples, it being understood that they are intended to be illustrative only and that the disclosure is not intended to be limited to the materials, conditions, process parameters and the like recited herein.

### EXAMPLES

### Example 1

A first pellicle membrane was made with a MoSiN core layer and two capping layers made from SiCN, having a structure as shown in FIG. 1. The core layer was thicker than each capping layer.

### Example 2

A second pellicle membrane was made with a structure as shown in FIG. 2. The core layer was made of MoSiN. The two inner sublayers were made of SiO₂. The two outer sublayers were made of SiCN. Each inner sublayer was thicker than the outer sublayer. Each inner sublayer and outer sublayer formed a capping layer. The core layer was thicker than each capping layer. The various layers had the same thicknesses as Example 1.

### Example 3

A third pellicle membrane was made with a MoSiN core layer and two capping layers made from SiOC, having a structure as shown in FIG. 1. The core layer was thicker than each capping layer, and the various layers had the same thicknesses as Example 1.

### Example 4

A fourth pellicle membrane was made with a structure as shown in FIG. 2. The core layer was made of MoSiN. The two inner sublayers were made of SiO₂. The two outer sublayers were made of SiOC. Each inner sublayer was thicker than the outer sublayer. Each inner sublayer and outer sublayer formed a capping layer. The core layer was thicker than each capping layer. The various layers had the same thicknesses as Example 1.

The various properties of the four example pellicle membranes were measured. Results are shown in Table A below:

TABLE A

| | Example 1 | Example 2 | Example 3 | Example 4 |
|---|---|---|---|---|
| EUVT % | 90.2 | ~90 | 89-90 | 89-90 |
| EUVT U % | 0.17 | <0.4 | <0.4 | <0.4 |
| EUVR % | 0.01 | <0.02 | <0.02 | <0.02 |
| DUVR % (193 nm) | 24.2 | 17.9 | 24.2 | 15.8 |
| DUVR % (248 nm) | 25.1 | 24.5 | 25.1 | 26.1 |
| Sag (μm) | 229 | >300 | >300 | >300 |

The four corners of the pellicle membrane of Example 1 were also measured for their critical dimension (CD), and compared to a conventional pellicle membrane. The results are shown in Table B below. Lower CD is desired.

TABLE B

| | Conventional | Example 1 |
|---|---|---|
| Corner 1 CD | 0.51 | 0.34 |
| Corner 2 CD | 0.41 | 0.24 |
| Corner 3 CD | 0.63 | 0.56 |
| Corner 4 CD | 0.46 | 0.26 |

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a pellicle membrane, comprising:
forming a first capping layer upon a substrate;
depositing molybdenum and silicon upon the first capping layer to form a core layer that comprises about 30 at % or more of Mo₃Si; and
forming a second capping layer upon the substrate to obtain the pellicle membrane.

2. The method of claim 1, further comprising annealing the core layer of the pellicle membrane at a temperature of about 800° C. to about 1200° C.

3. The method of claim 1, wherein the deposition of the first capping layer material, the molybdenum and silicon, and the second capping layer material are performed by chemical vapor deposition (CVD), physical vapor deposition (PVD), or atomic layer deposition (ALD).

4. The method of claim 1, further comprising:
applying a hardmask to a backside of the substrate;
patterning the hardmask;
etching through the patterned hardmask to obtain the pellicle membrane attached to a subframe.

5. The method of claim 1, wherein the hardmask is SiN or SiON.

6. The method of claim 1, wherein the core layer comprises:
about 30 at % or more of the Mo₃Si;
about 30 at % to about 50 at % of Mo₅Si₃; and
about 40 at % or less of SiN and MoSi₂ combined.

7. The method of claim 6, wherein the Mo₅Si₃ dominates the core layer within 2 nm of the first surface and the second surface.

8. The method of claim 1, wherein an Si:Mo molar ratio of the core layer is 1:1 or lower.

9. The method of claim 1, wherein the first capping layer and the second capping layer independently comprise SiCₓ, SiOₓC_{y}, or SiCₓN_{y}, where 0<x, y≤1.

10. The method of claim 1, wherein the first capping layer is formed by depositing a first outer sublayer upon the substrate and then depositing a first inner sublayer upon the first outer sublayer; and
wherein the second capping layer is formed by depositing a second inner sublayer upon the core layer and then depositing a second outer sublayer upon the second inner sublayer.

11. The method of claim 10, wherein the inner sublayer of the first capping layer, the outer sublayer of the first capping layer, the inner sublayer of the second capping layer, and the outer sublayer of the second capping layer independently have a thickness of about 1 nm to about 5 nm.

12. The method of claim 10, wherein the inner sublayer of the first capping layer and the inner sublayer of the second capping layer are made of the same material; and
wherein the outer sublayer of the first capping layer and the outer sublayer of the second capping layer are made of the same material.

13. The method of claim 10, wherein the inner sublayer of the first capping layer and the inner sublayer of the second capping layer comprise SiO₂; and
wherein the outer sublayer of the first capping layer and the outer sublayer of the second capping layer comprise SiOₓC_{y} or SiCₓN_{y}, where 0<x, y≤1.

14. The method of claim 10, wherein the inner sublayer of the first capping layer is thicker than the outer sublayer of the first capping layer; and
wherein the inner sublayer of the second capping layer is thicker than the outer sublayer of the second capping layer.

15. The method of claim 1, wherein the core layer has a thickness of about 8 nm to about 12 nm.

16. The method of claim 1, wherein the first capping layer and the second capping layer independently have a thickness of about 1 nm to about 5 nm.

17. A pellicle membrane, comprising:
a core layer comprising SiN, MoSi₂, Mo₅Si₃, and Mo₃Si;
a first capping layer on a first surface of the core layer; and
a second capping layer on a second surface of the core layer.

18. The pellicle membrane of claim 17, wherein the membrane has a thickness of about 10 nm to about 30 nm.

19. A method of forming a pellicle assembly, comprising:
forming a first capping layer upon a substrate;
forming a core layer upon the first capping layer;
annealing the core layer;
forming a second capping layer upon the core layer to obtain the pellicle membrane;
applying a hardmask to a backside of the substrate;
patterning the hardmask;
etching through the patterned hardmask to obtain the pellicle membrane attached to a subframe; and
attaching the subframe to a mounting frame to obtain the pellicle assembly;
wherein the first capping layer and the second capping layer comprise SiCₓ, SiOₓC_{y}, or SiCₓN_{y}, where 0<x, y≤1.

20. The method of claim 19, wherein the first capping layer Is formed by depositing a first outer sublayer material upon the substrate to form a first outer sublayer of the first capping layer, and then depositing a first inner sublayer material upon the first outer sublayer to form a first inner sublayer of the first capping layer; and
wherein the second capping layer is formed by depositing a second inner sublayer material upon the core layer to form a second inner sublayer of the second capping layer, and then depositing a second outer sublayer material upon the second inner sublayer to form a second outer sublayer of the second capping layer.
